(19) United States
(12) Patent Application Publication
(10) Pub. No.: US 2020/0373906 A1
(43) Pub. Date: Nov. 26, 2020

(54) PIEZOELECTRIC VIBRATION DEVICE

(71) Applicant: DAISHINKU CORPORATION, Kakogawa-shi (JP)

(72) Inventor: Hiroki YOSHIOKA, Kakogawa-shi (JP)

(21) Appl. No.: 16/959,832

(22) PCT Filed: Mar. 20, 2019
(86) PCT No.: PCT/JP2019/011748

§ 371 Date: Jul. 2, 2020

(30) Foreign Application Priority Data
Mar. 28, 2018 (JP) 2018-062951
Apr. 10, 2018 (JP) 2018-075282

(51) Int. Cl. H03H 9/08; H03H 9/05; H03H 9/10

(52) U.S. Cl. CPC H03H 9/08; H03H 9/1035; H03H 9/0547; H03H 9/0523

(57) ABSTRACT

The piezoelectric vibration device disclosed herein includes: a piezoelectric vibrator including a plurality of terminals for external connection and a plurality of electrodes for mounting purpose; and an integrated circuit element mountable to the piezoelectric vibrator and including a plurality of mounting terminals connectable to the plurality of electrodes for mounting purpose. At least one of the electrodes for mounting purpose connected to the terminals for external connection has a wiring pattern extending more inward in a mounting region where the integrated circuit element is mounted than the mounting terminals of the integrated circuit element.

### TECHNICAL FIELD

This invention relates to piezoelectric vibration devices for use in variously different electronic instruments including communication devices.

### BACKGROUND ART

Surface-mounted piezoelectric vibrators and oscillators are typical examples of the piezoelectric vibration devices which have been and are currently used in a broad range of applications. For example, temperature-compensated piezoelectric oscillators that can compensate frequency-temperature characteristics of piezoelectric vibrators are more commonly used as frequency sources for mobile communication devices often exposed to different thermal environments.

The temperature-compensated piezoelectric oscillator is equipped with an integrated circuit element that includes a temperature sensor and a temperature-compensated circuit. The temperature-compensated piezoelectric oscillator is configured to generate a compensation voltage to control an oscillation frequency based on temperatures detected by the temperature sensor embedded in the integrated circuit element (for example, patent document 1).

### CITATION LIST

### Patent Document

### Patent Document 1: JP 2005-006030 A

### SUMMARY OF INVENTION

### Technical Problem

In such a surface-mounted, temperature-compensated piezoelectric oscillator, terminals for external connection are joined, with a joining material such as solder, to an external circuit board. Any heat generated from electronic components, which are a heat source mounted on the external circuit board (for example, power transistors), is transferred to the temperature-compensated piezoelectric oscillator mounted on this circuit board.

The electronic components; heat source, mounted on the external circuit board generates heat very fast as soon as they are turned on and supplied with electric power. These electronic components may be arranged in variously different manners on the external circuit board. Depending on how they are arranged, heat from the external circuit board may often cause temperature differences between the temperature sensor of the integrated circuit element and the piezoelectric vibrator of the temperature-compensated piezoelectric oscillator.

Taking, for instance, a temperature-compensated piezoelectric oscillator in which a piezoelectric vibrator is located closer to the external circuit board than the integrated circuit element, heat from the external circuit board mounted with this piezoelectric oscillator may invite the temperature of the piezoelectric vibrator to elevate to higher degrees than that of the integrated circuit element, thus causing differences in temperature between these circuit element and vibrator. Then, accurate temperature compensation may be difficult to perform, leading to frequency variations, i.e., frequency drift, until the piezoelectric vibrator and the integrated circuit element can reach the state of thermal equilibrium with no temperature difference between them.

This unfavorable event may be particularly noticeable with any electronic devices in which electronic components; heat source, mounted on the external circuit are electrically turned on and off very often.

This invention addresses these issues and is directed to minimize the risk of temperature differences that may occur between the piezoelectric vibrator and the integrated circuit element under heat transferred from the external circuit board mounted with the piezoelectric vibration device.

### Solution to the Problems

To this end, this invention provides the following technical features.

A piezoelectric vibration device is provided that includes:

a piezoelectric vibrator including a plurality of terminals for external connection and a plurality of electrodes for mounting purpose; and

an integrated circuit element including a plurality of mounting terminals connectable to the plurality of electrodes for mounting purpose, the integrated circuit element being mountable to the piezoelectric vibrator.

The piezoelectric vibration device is further characterized in that

the piezoelectric vibrator includes:

a piezoelectric vibrating plate including driving electrodes formed on main surfaces on both sides thereof;

a first sealing member allowed to cover and seal one of the main surfaces of the piezoelectric vibrating plate; and

a second sealing member allowed to cover and seal the other one of the main surfaces of the piezoelectric vibrating plate,

the plurality of electrodes for mounting purpose are electrically connected to the driving electrodes formed on the main surfaces or to the plurality of terminals for external connection,

the plurality of mounting terminals in the integrated circuit element are formed at positions close to an outer circumference, and

at least one of the plurality of electrodes for mounting purpose electrically connected to the plurality of terminals for external connection has a wiring pattern extending more inward in a mounting region where the integrated circuit element is mounted than at least the plurality of mounting terminals.

In the piezoelectric vibration device of this invention, at least one of the electrodes for mounting purpose electrically connected to the terminals for external connection has a wiring pattern extending more inward in the mounting region of the integrated circuit element than the mounting terminals. In the piezoelectric vibration device thus characterized, heat generated from an external circuit board mounted with the piezoelectric vibration device is transferred to the terminals for external connection joined to the external circuit board and the wiring patterns extending inward in the mounting region of the electrodes for mounting purpose electrically connected to these terminals for external connection. Thus, the temperature of the integrated circuit element in the mounting region may be increased to higher degrees under the heat generated from the external circuit board and transferred to the wiring patterns.

When the piezoelectric vibration device is mounted on the external circuit board, the piezoelectric vibrator located closer to the external circuit board than the integrated circuit element may be often heated to higher temperatures under the heat from the external circuit board. Possible temperature differences between the piezoelectric vibrator and the integrate circuit element, however, may be adequately controlled by increasing the temperature of the integrated circuit element as described earlier. This may allow the piezoelectric vibrator and the integrate circuit element to rapidly reach the state of thermal equilibrium.

The piezoelectric vibrator has a multilayered structure including three layers; the piezoelectric vibrating plate having main surfaces on which the driving electrodes are formed, and the first and second sealing members covering and sealing the main surfaces. The piezoelectric vibrator thus structured may be advantageously reduced in thickness (reduced in height) as compared with, for example, such a packaging structure that piezoelectric vibration pieces are housed in the housing space of a container and sealed with a lid member.

In the piezoelectric vibration device, the plurality of electrodes for mounting purpose and the wiring pattern may be formed on an outer surface of the first sealing member, the plurality of terminals for external connection may be formed on an outer surface of the second sealing member, and the piezoelectric vibrator may include a plurality of through electrodes penetrating through the first sealing member, the piezoelectric vibrating plate and the second sealing member in a direction of thickness to provide electric connection between the plurality of electrodes for mounting purpose and the plurality of terminals for external connection.

The terminals for external connection joined to the external circuit board are formed on the outer surface of the second sealing member on one surface of the piezoelectric vibrator. The electrodes for mounting purpose connected to the mounting terminals of the integrated circuit element are formed on the outer surface of the first sealing member on the other surface of the piezoelectric vibrator. In this instance, the integrated circuit element is mounted on one surface of the piezoelectric vibrator opposite to the other surface joined to the external circuit board. When electronic components; heat source, of the external circuit board are turned on, they may generate heat very fast. Then, the generated heat may be transferred from the external circuit board to the piezoelectric vibrator via the terminals for external connection of the piezoelectric vibration device joined to the external circuit board, and then transferred to the integrated circuit element mounted on the surface on the opposite side of the surface where the terminals for external connection are formed.

When the electronic components; heat source, of the external circuit generate and transfer heat to the piezoelectric vibration device, the transferred heat heats the piezoelectric vibrator first and then heats the integrated circuit element, thus causing temperature differences between the piezoelectric vibrator and the integrated circuit element.

The heat generated from the external circuit board may be transferred to the piezoelectric vibrator through the terminals for external connection, by which the piezoelectric vibrator may be heated to higher temperatures than that of the integrated circuit element. In the piezoelectric vibration device characterized as described earlier, however, the electrodes for mounting purpose electrically connected to the terminals for external connection via the through electrodes have the wiring patterns extending inward in the mounting region of the integrated circuit element. The heat generated from the external circuit board, therefore, may be transferred to the wiring patterns of the electrodes for mounting purpose via the terminals for external connection and the through electrodes. Thus, the integrated circuit element in the mounting region may be invited to increase in temperature under the heat generated from the external circuit board and transferred to the wiring patterns extending inward in the mounting region. This may rapidly dissipate any differences between the temperatures of the integrated circuit element and of the piezoelectric vibrator, allowing the integrated circuit element and the piezoelectric vibrator to reach the state of thermal equilibrium.

In the piezoelectric vibration device, the wiring pattern may be extending inward in the mounting region of the integrated circuit element as far as at least a near-center part of the mounting region.

The wiring patterns of the electrodes for mounting purpose electrically connected to the terminals for external connection are extending as far as the near-center part of the mounting region of the integrated circuit element. In the piezoelectric vibration device thus characterized, the near-center part of the integrated circuit element in the mounting region may be invited to increase in temperature under the heat generated from the external circuit board and transferred to the wiring patterns of the electrodes for mounting purpose. This may efficiently heat the integrated circuit element to higher temperatures.

In the piezoelectric vibration device, the wiring pattern may be formed so as to electrically connect at least one of the plurality of electrodes for mounting purpose to the plurality of terminals for external connection.

The wiring patterns thus characterized may have two advantages; the integrated circuit element may be increased in temperature under the heat generated from the external circuit board and transferred via the terminals for external connection, and the wiring patterns per se may provide electric connection between the electrodes for mounting purpose and the terminals for external connection.

In the piezoelectric vibration device, the at least one of the plurality of electrodes for mounting purpose may be electrically connected to one or more of the plurality of terminals for external connection electrically connected to an electronic component; heat source, mounted to an external circuit board.

The electrodes for mounting purpose having the wiring patterns are electrically connected to the terminals for external connection electrically connected to the electronic components; heat source, mounted on the external circuit board. Thus, the heat transferred to the wiring patterns from the electronic components that generate heat of the external circuit board may more efficiently heat the integrated circuit element to higher temperatures.

In the piezoelectric vibration device, the integrated circuit element may include a temperature sensor, and the wiring pattern may be extending so as to overlap at least in part with a region of projection where the temperature sensor is projected in the mounting region of the integrated circuit element.

Thus, the wiring pattern is formed so as to overlap at least in part with the temperature sensor-projected region. The temperature sensor-embedded part of the integrated circuit element may be thus efficiently heated to higher temperatures under the heat generated from the external circuit board and transferred to the wiring pattern. While the piezoelectric vibrator is often heated to higher temperatures than the integrated circuit element, possible temperature differences between the piezoelectric vibrator and the temperature sensor of the integrated circuit element may be rapidly dissipated. Thus, the integrated circuit element and the piezoelectric vibrator may be allowed to rapidly reach the state of thermal equilibrium.

When the integrated circuit element compensates the frequency-temperature characteristics of the piezoelectric vibrator based on the temperatures detected by the temperature sensor, frequency variations resulting from any temperature differences between the piezoelectric vibrator and the temperature sensor may be adequately controlled, and accurate temperature compensation may be successfully performed.

In the piezoelectric vibration device, the integrated circuit element may have a rectangular shape in plan view, the plurality of mounting terminals may be formed at positions close to one of two pairs of opposing sides of the rectangular shape and arranged in two rows along the one of two pairs of opposing sides, and the wiring pattern may be formed so as to extend and traverse an interval between the two rows in the mounting region of the integrated circuit element.

In the piezoelectric vibration device characterized in that the wiring pattern extends so as to traverse an interval between the two rows of the mounting terminals formed at positions close to a pair of opposing sides of the integrated circuit element rectangular in plan view, a part of the integrated circuit element in the mounting region between two rows of the mounting terminals close to the outer circumference, i.e., a center part of the integrated circuit element, may be invited to rapidly increase in temperature under the heat generated from the external circuit board and transferred to the wiring pattern. Thus, the integrated circuit element may be rapidly heated to higher temperatures.

In the piezoelectric vibration device, the integrated circuit element may be mounted on the piezoelectric vibrator in a manner that, of the plurality of electrodes for mounting purpose electrically connected to the driving electrodes formed on the main surfaces, a part of the plurality of electrodes for mounting purpose extending beyond the mounting region is located at a position close to the one of two pairs of opposing sides of the integrated circuit element.

In the piezoelectric vibration device thus characterized, of the electrodes for mounting purpose electrically connected to the driving electrodes, a part of these electrodes extending beyond the mounting region is located at a position close to the one of two pairs of opposing sides of the integrated circuit element. Then, a sealing resin, when used to seal the integrated circuit element and the piezoelectric vibrator, may be injected into between these circuit element and vibrator through these paired opposing sides, and a part of the electrodes for mounting purpose extending beyond the mounting region may be covered with the sealing resin.

In the piezoelectric vibration device, an active surface of the integrated circuit element may be facing the plurality of electrodes for mounting purpose of the piezoelectric vibrator, and the plurality of mounting terminals of the integrated circuit element and the plurality of electrodes for mounting purpose of the piezoelectric vibrator may be electrically connected through a metallic material.

In the piezoelectric vibration device thus characterized, the piezoelectric vibrator and the active surface of the integrated circuit element are located in proximity. The heat of the piezoelectric vibrator, therefore, may be efficiently transferred to the integrated circuit element through the metallic material, and the temperature of the integrated circuit element may be accordingly increased to higher degrees.

In the piezoelectric vibration device, an interval between the integrated circuit element and the piezoelectric vibrator may be filled with a sealing resin.

This may ensure an adequate mechanical strength between the integrated circuit element and the piezoelectric vibrator.

### Effects of the Invention

In this invention, at least one of the electrodes for mounting purpose electrically connected to the terminals for external connection has a wiring pattern extending more inward in the mounting region of the integrated circuit than the mounting terminals. In the piezoelectric vibration device thus characterized, heat generated from the external circuit board mounted with the piezoelectric vibration device may be transferred to the terminals for external connection joined to the external circuit board and the wiring patterns extending inward in the mounting region of the electrodes for mounting purpose electrically connected to the terminals for external connection. The heat transferred to the wiring patterns may rapidly heat the integrated circuit element in the mounting region to higher temperatures. In case the temperature of the piezoelectric vibrator is elevated to higher degrees than that of the integrated circuit element under heat from the external circuit board, therefore, any temperature differences between the piezoelectric vibrator and the integrated circuit element may be thus sufficiently controlled. This may allow the piezoelectric vibrator and the integrated circuit element to rapidly reach the state of thermal equilibrium.

The piezoelectric vibrator has a multilayered structure including three layers; the piezoelectric vibrating plate having main surfaces on which the driving electrodes are formed, and the first and second sealing members covering the main surfaces. The piezoelectric vibrator thus structured may be advantageously reduced in thickness (reduced in height) as compared with, for example, such a packaging structure that piezoelectric vibration pieces are housed in the housing space of a container and sealed with a lid member.

### BRIEF DESCRIPTION OF DRAWINGS

FIG. 1 is a schematic structural view of a temperature-compensated crystal oscillator according to an embodiment of this invention.

FIG. 2 is a schematic plan view illustrating the side of one main surface of a crystal vibrating plate shown FIG. 1.

FIG. 3 is a schematic plan view illustrating the side of the other main surface of the crystal vibrating plate seen through from the side of the one main surface.

FIG. 4 is a schematic plan view illustrating the side of one main surface of a first sealing member shown in FIG. 1.

FIG. 5 is a schematic plan view illustrating the side of the other main surface of the first sealing member seen through from the side of the one main surface.

FIG. 6 is a schematic plan view illustrating the side of one main surface of a second sealing member shown in FIG. 1.

FIG. 7 is a schematic plan view illustrating the side of the other main surface of the second sealing member seen through from the side of the one main surface.

FIG. 8 is a schematic structural view of a temperature-compensated crystal oscillator according to an embodiment of another invention.

FIG. 9 is a schematic plan view illustrating the side of one main surface of a crystal vibrating plate shown in FIG. 8.

FIG. 10 is a schematic plan view illustrating the side of the other main surface of the crystal vibrating plate seen through from the side of the one main surface.

FIG. 11 is a schematic plan view illustrating the side of one main surface of a first sealing member shown in FIG. 8.

FIG. 12 is a schematic plan view illustrating the side of the other main surface of the first sealing member seen through from the side of the one main surface.

FIG. 13 is a schematic plan view illustrating the side of one main surface of a second sealing member shown in FIG. 8.

FIG. 14 is a schematic plan view illustrating the side of the other main surface of the second sealing member seen through from the side of the one main surface.

FIG. 15 is a schematic view illustrating the side of one main surface of a first sealing member according to another embodiment of the another invention.

### DESCRIPTION OF EMBODIMENTS

An embodiment of this invention is hereinafter described with reference to the accompanying drawings. In this embodiment, a temperature-compensated crystal oscillator is described as an example of the piezoelectric vibration device.

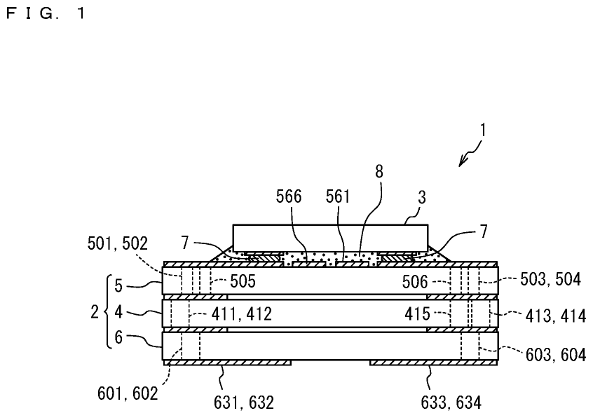

FIG. 1 is a schematic structural view of a temperature-compensated crystal oscillator according to an embodiment of this invention.

A temperature-compensated crystal oscillator 1 according to this embodiment includes a crystal vibrator 2, and an IC3; integrated circuit element, mounted on the crystal vibrator 2.

The crystal vibrator 2 includes a crystal vibrating plate 4; an example of the piezoelectric vibrating plate, a first sealing member 5 used to cover and air-tightly seal the side of one main surface of the crystal vibrating plate 4, and a second sealing member 6 used to cover and air-tightly seal the side of the other main surface of the crystal vibrating plate 4.

The crystal vibrator 2 is produced in the form of a multilayered package in which the first and second sealing members 5 and 6 are respectively joined to one and the other main surfaces of the crystal vibrating plate 4. The package of the crystal vibrator 2 has a cuboidal shape and is rectangular in plan view. In this embodiment, this package is in the size of, for example, 1.0 mm×0.8 mm in plan view and is thus reduced in size and height.

The package may be thus sized or may be selected from other applicable dimensions.

The IC3 mounted on the crystal vibrator 2 is an integrated circuit element having a cuboidal outer shape in which an oscillator circuit, a temperature sensor and a temperature-compensated circuit are combined into one chip.

The crystal vibrating plate 4 and the first and second sealing members 5 and 6 of the crystal vibrator 2 are hereinafter described.

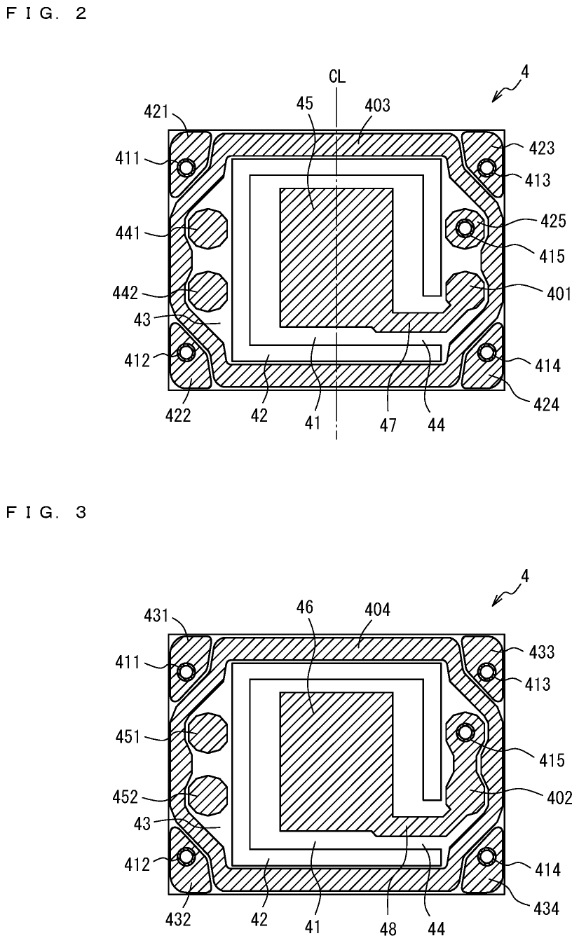

FIG. 2 is a schematic plan view illustrating the side of one main surface of the crystal vibrating plate 4. FIG. 3 is a schematic plan view illustrating the side of the other main surface of the crystal vibrating plate 4 seen through from the one main-surface side.

In the description given below, one main surface close to the IC3 (upper side in FIG. 1) is referred to as a front surface, and the other main surface away from the IC3 (lower side in FIG. 1) is referred to as a back surface. FIG. 2 is a schematic plan view illustrating the front-surface side of the crystal vibrating plate 4, and FIG. 3 is a schematic plan view illustrating the back-surface side of the crystal vibrating plate 4 seen through from the front-surface side.

The crystal vibrating plate 4 according to this embodiment is an AT-cut crystal plate, main surfaces of which on front and back sides are both XZ′ planes.

The crystal vibrating plate 4 includes a substantially rectangular vibrating portion 41, a frame portion 43 surrounding the vibrating portion 41 across a space (void) 12, and a coupling portion 44 that couples the vibrating portion 41 and the frame portion 43 to each other. The vibrating portion 41, frame portion 43 and coupling portion 44 are formed as an integral unit. Though not illustrated in the drawings, the vibrating portion 41 and the coupling portion 44 are smaller in thickness than the frame portion 43.

First and second driving electrodes 45 and 46 are formed in a pair on main surfaces on front and back sides of the vibrating portion 41. First and second extraction electrodes 47 and 48 are respectively extracted from the first and second driving electrodes 45 and 46. The first extraction electrode 47 on the front-surface side is extracted, through the coupling portion 44, to a junction pattern 401 for connecting purpose formed in the frame portion 43. The second extraction electrode 47 on the back-surface side is extracted, through the coupling portion 44, to a junction pattern 402 for connecting purpose formed in the frame portion 43. The junction pattern 402 for connecting purpose is formed so as to extend along a short side of the crystal vibrating plate 4 rectangular in plan view and to surround a fifth through electrode 415 described later.

In this embodiment, the vibrating portion 41 is coupled to the frame portion 43 at a position through the coupling portion 44. This may reduce any stress possibly acting upon the vibration portion 41, as compared with the vibrating portion 41 being coupled to the frame portion 43 at two or more positions.

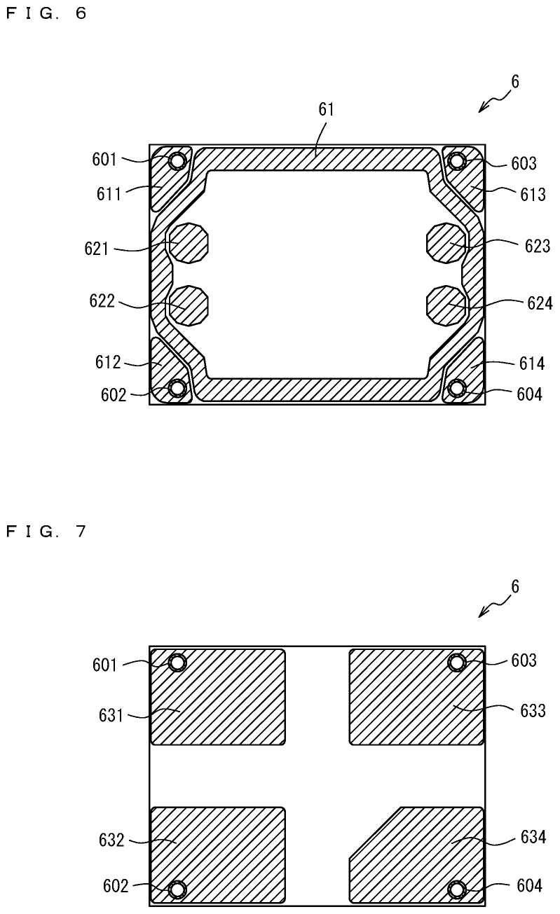

On the front and back main surfaces of the crystal vibrating plate 4 are respectively formed first and second junction patterns 403 and 404 for sealing purpose serving to join the crystal vibrating plate 4 to the first and second sealing members 5 and 6. The first and second junction patterns 403 and 404 on these main surfaces are formed in a circular shape along the whole circumference of the frame portion 43 and substantially along the outer peripheral edge of the crystal vibrating plate 4 except its four corners. As illustrated in FIG. 5, a first junction pattern 51 for sealing purpose is formed on the back surface of the first sealing member 5. This junction pattern 51 is formed correspondingly to the first junction pattern 403 for sealing purpose on the front surface of the crystal vibrating plate 4. As illustrated in FIG. 6, a second junction pattern 61 for sealing purpose is formed on the front surface of the second sealing member 6. This junction pattern 61 is formed correspondingly to the second junction pattern 403 for sealing purpose on the back surface of the crystal vibrating plate 4.

As described later, the first sealing member 5, crystal vibrating plate 4 and second sealing member 6 are stacked in layers, and the circular first junction patterns 51 and 403 for sealing purpose of the first sealing member 5 and of the crystal vibrating plate 4 are joined by diffusion bonding. Further, the circular second junction patterns 61 and 404 for sealing purpose of the second sealing member 6 and of the crystal vibrating plate 4 are joined by diffusion bonding. Thus, the front and back surfaces of the crystal vibrating plate 4 are sealed to each other with the first and second sealing members 5 and 6, and a housing space is formed in which the vibrating portion 41 of the crystal vibrating plate 4 is housed.

A package is thus formed in which the vibrating portion 41 is housed in a space formed by three crystal plates stacked on one another, i.e., the crystal vibrating plate 4 and the first and second sealing members 5 and 6. This package, therefore, may be reduced in thickness (reduced in height), as compared with crystal vibrators so structured that crystal vibrating pieces are housed in the housing recess of a ceramic container and sealed with a lid member joined to the container.

As illustrated in FIGS. 2 and 3, the crystal vibrating plate 4 has five through electrodes; first to fifth through electrodes 411 to 415, which are formed so as to penetrate through the front and back main surfaces of the crystal vibrating plate 4. In these through electrodes 411 to 415, inner wall surfaces of through holes are each coated with a metal film. The first to fourth through electrodes 411 to 414 are formed at positions in four corners of the crystal vibrating plate 4 on the outer side of the circular first and second junction patterns 403 and 404 for sealing purpose. The fifth through electrode 415 is formed at a position of the frame portion 43 on the inner side of the circular first and second junction patterns 403 and 404 for sealing purpose and close to a short side of the crystal vibrating plate 4 rectangular in plan view.

Junction patterns 421 to 424 for connecting purpose are formed at positions around the through electrodes 411 to 414 in four corners of the front surface of the crystal vibrating plate 4 and on the outer side of the circular first junction pattern 403 for sealing purpose. The through electrodes 411 to 414 are electrically connected to the junction patterns 421 to 424 for connecting purpose.

Junction patterns 431 to 434 for connecting purpose are formed at positions around the through electrodes 411 to 414 in four corners of the back surface of the crystal vibrating plate 4 and on the outer side of the circular second junction pattern 404 for sealing purpose. The through electrodes 411 to 414 are electrically connected to the junction patterns 431 to 434 for connecting purpose.

As described later, the first sealing member 5 and the second sealing member 6 respectively have first to fourth through electrodes 501 to 504 and first to fourth through electrodes 601 to 604 that are formed correspondingly to the first to fourth through electrodes 411 to 414 of the crystal vibrating plate 4 (see FIGS. 5 and 6).

As illustrated in FIG. 2, a junction pattern 425 for connecting purpose is formed around the fifth through electrode 415 on the front surface of the crystal vibrating plate 4. The fifth through electrode 415 and the junction pattern 425 for connecting purpose are electrically connected to each other.

As illustrated in FIG. 3, the junction pattern 401 for connecting purpose 402, which is connected to the extraction electrode 48 extracted from the second driving electrode 46, is formed around the fifth through electrode 415 on the back surface of the crystal vibrating plate 4. The fifth through electrode 415 is electrically connected to the junction pattern 402 for connecting purpose and is thus electrically connected to the second driving electrode 46.

On one side of the front surface of the crystal vibrating plate 4 in a direction along its long sides across the vibrating portion 41 (lateral direction in FIG. 2), the junction pattern 425 for connecting purpose is formed around the fifth through electrode 415, and the junction pattern 401 for connecting purpose is formed to be continuous to the first extraction electrode 47, as illustrated in FIG. 2. On the other side of the front surface of the crystal vibrating plate 4 in the same direction are formed two junction patterns 441 and 442 for connecting purpose.

The junction patterns 425 and 401 for connecting purpose and the junction patterns 441 and 442 for connecting purpose are substantially symmetric with respect to a center line CL drawn at the center of long sides of the crystal vibrating plate 4. Also, the junction patterns 425 and 441 for connecting purpose and the junction patterns 401 and 442 for connecting purpose are substantially symmetric with respect to a center line drawn at the center of short sides of the crystal vibrating plate 4. Thus, the junction patterns 425 and 401 for connecting purpose and the junction patterns 441 and 442 for connecting purpose are substantially symmetric, respectively, in the direction along long sides and in the direction along short sides of the crystal vibrating plate 4.

The junction patterns 421 to 424 for connecting purpose formed around the through electrodes 411 to 414 at positions in four corners of the front surface of the crystal vibrating plate 4 are also symmetric in the direction along long sides and in the direction along short sides of the crystal vibrating plate 4.

This structural feature; the junction patterns 425 and 401, 441 and 442, 421 to 424 being symmetric or substantially symmetric in the direction along long sides and in the direction along short sides of the crystal vibrating plate 4, may allow a pressing force to be equally applied at the time of diffusion bonding.

As with the front surface of the crystal vibrating plate 4, the junction pattern 402 for connecting purpose extended to the fifth through electrode 415 is formed on the back surface of the crystal vibrating plate 4. The junction pattern 402 for connecting purpose is formed on one side in the direction along long sides of the crystal vibrating plate 4 across the vibrating portion 41 (lateral direction in FIG. 3). Two junction patterns 451 and 452 for connecting purpose are formed on the other side in the direction along long sides of the crystal vibrating plate 4. The junction pattern 402 for connecting purpose and the junction patterns 451 and 452 for connecting purpose are also substantially symmetric in the direction along long sides and in the direction along short sides of the crystal vibrating plate 4.

The junction patterns 431 to 434 for connecting purpose formed around the through electrodes 411 to 414 at positions in four corners of the back surface of the crystal vibrating plate 4 are also symmetric in the direction along long sides and in the direction along short sides of the crystal vibrating plate 4.

The electrodes and junction patterns of the crystal vibrating plate 4; first and second driving electrodes 45 and 46, first and second extraction electrodes 47 and 48, first and second junction patterns 403 and 404 for sealing purpose, and junction patterns 401, 402, 421 to 425, 431 to 434, 441, 442, 451 and 452 for connecting purpose, may be so structured that an Au layer is stacked on a ground layer including, for example, Ti or Cr.

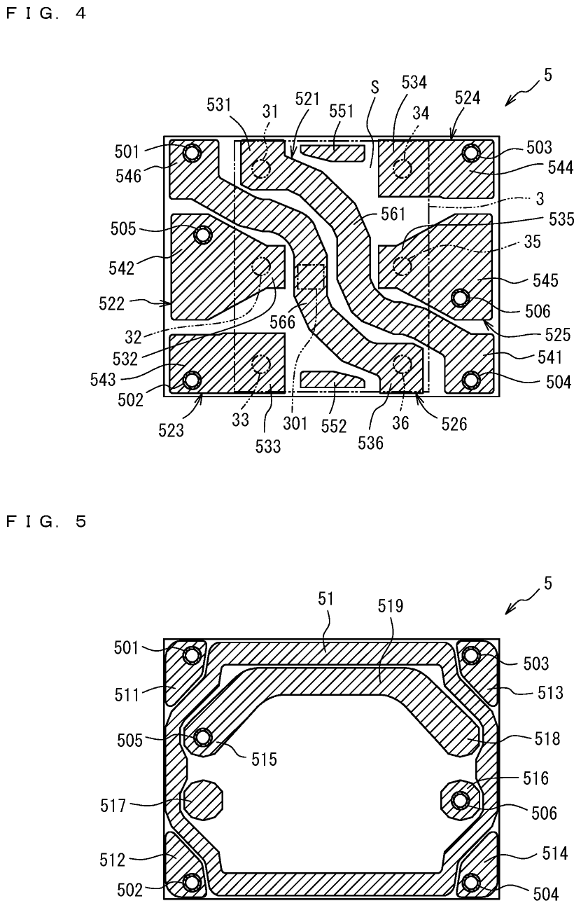

FIG. 4 is a schematic plan view illustrating the front-surface side of the first sealing member 5. FIG. 5 is a schematic plan view illustrating the back-surface side the first sealing member 5 seen through from the front-surface side.

The first sealing member 5 is a cuboidal substrate including an AT-cut crystal plate, similarly to the crystal vibrating plate 4. As illustrated in FIG. 5, the first sealing member 5 has, on its back surface, the first junction pattern 51 for sealing purpose to be joined for sealing to the first junction pattern 403 for sealing purpose on the front surface of the crystal vibrating plate 4. This first junction pattern 51 is formed in a circular shape along the whole circumference of the first sealing member 5 and substantially along the outer peripheral edge of the first sealing member 5 except its four corners.

The first sealing member 5 has six through electrodes; first to sixth through electrodes 501 to 506, which are formed so as to penetrate through the front and back main surfaces of the first sealing member 5. In these through electrodes 501 to 506, inner wall surfaces of through holes are each coated with a metal film. As with the first to fourth through electrodes 411 to 414 of the crystal vibrating plate 4, the first to fourth through electrodes 501 to 504 are formed at positions in four corners of the first sealing member 5 rectangular in plan view. The fifth through electrode 505 is formed, correspondingly to the junction pattern 441 for connecting purpose on the front surface of the crystal vibrating plate 4, at a position on the inner side of the circular first junction pattern 51 for sealing purpose and close to a short side of the rectangular first sealing member 5. The sixth through electrode 506 is formed, correspondingly to the junction pattern 401 for connecting purpose on the front surface of the crystal vibrating plate 4, at a position on the inner side of the circular first junction pattern 51 for sealing purpose and close to the other short side of the rectangular first sealing member 5.

As illustrated in FIG. 5, junction patterns 511 to 514 for connecting purpose are formed around the through electrodes 501 to 504 formed at positions in four corners of the back surface of the first sealing member 5. The through electrodes 501 to 504 are electrically connected, respectively, to the junction patterns 511 to 514 for connecting purpose.

A junction pattern 515 for connecting purpose is formed around the fifth through electrode 505 on the back surface of the first sealing member 5. The fifth through electrode 505 is electrically connected to the junction pattern 515 for connecting purpose. A junction pattern 518 for connecting purpose is formed, correspondingly to the junction pattern 425 for connecting purpose on the front surface of the crystal vibrating plate 4, at a position on the opposite side of the junction pattern 515 for connecting purpose in the direction along long sides of the first sealing member 5 (lateral direction in FIG. 5). The junction pattern 518 for connecting purpose and the junction pattern 515 for connecting purpose formed around the fifth through electrode 505 are electrically connected to each other through a wiring pattern 519 for connecting purpose. The junction pattern 518 for connecting purpose on the back surface of the first sealing member 5 is, therefore, electrically connected to the fifth through electrode 505 of the first sealing member 5.

As described later, the junction pattern 518 for connecting purpose of the first sealing member 5 is joined by diffusion bonding to the junction pattern 425 for connecting purpose formed around the fifth through electrode 415 on the front surface of the crystal vibrating plate 4. The junction pattern 518 for connecting purpose is thus electrically connected to the fifth through electrode 415 of the crystal vibrating plate 4. The fifth through electrode 415 of the crystal vibrating plate 4 is electrically connected to the second driving electrode 46 formed on the back surface of the crystal vibrating plate 4. Therefore, the junction pattern 518 for connecting purpose of the first sealing member 5 is electrically connected to the second driving electrode 46 of the crystal vibrating plate 4. The junction pattern 518 for connecting purpose of the first sealing member 5 is electrically connected to the junction pattern 515 for connecting purpose formed around the fifth through electrode 505 through the wiring pattern 519 for connecting purpose. Therefore, the second driving electrode 46 formed on the back surface of the crystal vibrating plate 4 is electrically connected to the fifth through electrode 505 of the first sealing member 5 through the fifth through electrode 415 of the crystal vibrating plate 4 and the junction patterns 518, 519 and 515 for connecting purpose of the first sealing member 5.

A junction pattern 516 for connecting purpose is formed, correspondingly to the junction pattern 401 for connecting purpose on the front surface of the crystal vibrating plate 4, around the sixth through electrode 506 on the back surface of the first sealing member 5. The sixth through electrode 506 is electrically connected to the junction pattern 516 for connecting purpose.

As described later, the junction pattern 516 for connecting purpose of the first sealing member 5 is joined by diffusion bonding to the junction pattern 401 for connecting purpose formed on the front surface of the crystal vibrating plate 4. The junction pattern 516 for connecting purpose is, therefore, electrically connected to the first driving electrode 45 through the junction pattern 401 for connecting purpose and the first extraction electrode 47. The sixth through electrode 506 of the first sealing member 5 is thus electrically connected to the first driving electrode 45 of the crystal vibrating plate 4.

As with the crystal vibrating plate 4, the junction patterns 515 to 518 for connecting purpose formed on the back surface of the first sealing member 5 are substantially symmetric in the directions along short and long sides of this sealing member to allow a pressing force to be equally applied at the time of junction bonding. The junction patterns 511 to 514 for connecting purpose formed around the through electrodes 501 to 504 at positions in four corners of the back surface of the first sealing member 5 are also symmetric in the directions along short and long sides of the first sealing member 5.

The front surface of the first sealing member 5 is a surface to be mounted with the IC3. In FIG. 4 showing the front surface of the first sealing member 5, virtual lines are used to illustrate the rectangular outer shape of the IC3 in plan view mounted on the first sealing member 5 and outer shapes of the first to sixth mounting terminals 31 to 36 and the temperature sensor 301 of the IC3.

As illustrated in FIG. 4, first to sixth electrodes 521 to 526 for mounting purpose are formed on the front surface of the first sealing member 5. The first to sixth mounting terminals 31 to 36 of the IC3 are respectively connected to these electrodes 521 to 526 for mounting purpose.

In a rectangular mounting region S defined with a virtual line where the IC3 is mounted, the first to sixth electrodes 521 to 526 for mounting purpose have first to sixth terminal junctions 531 to 536 including electrode pads (not illustrated in the drawings) to which the mounting terminals 31 to 36 of the IC3 are connectable. The first to sixth electrodes 521 to 526 for mounting purpose further have first to sixth electrode connectors 541 to 546 electrically connectable to the through electrodes, 504, 505, 502, 503, 506 and 501. These electrode connectors 541 to 546 extend from the first to sixth terminal junctions 531 to 536 in the mounting region S toward the outside of the mounting region S.

At mid positions close to short sides of the rectangular mounting region S, junction patterns 551 and 552 for connecting purpose are extending along the short sides.

As illustrated in FIG. 1, the IC3 is joined, with a metallic member; metal bumps 7 (for example, Au bumps), to the front surface of the first sealing member 5 by the FCB (flip-chip bonding). Instead of the metal bumps 7, metal plating or metal paste may be used for bonding.

An interval between the IC3 and the first sealing member 5 is filled with a sealing resin; underfill resin 8, to protect the acting surface of the IC3 and to ensure a mechanical bonding strength required.

As with the first and second junction patterns 403 and 404 for sealing purpose of the crystal vibrating plate 4, the respective patterns and electrodes of the first sealing member 5; the first junction pattern 51 for sealing purpose, junction patterns 511 to 518, 551 and 552 for connecting purpose, wiring pattern 519 for connecting purpose, and first to sixth electrodes 521 to 526 for mounting purpose, are so structured that an Au layer is stacked on a ground layer including, for example, Ti or Cr.

The other structural features of the front surface of the first sealing member 5 will be described later.

FIG. 6 is a schematic plan view illustrating the front-surface side of the second sealing member 6. FIG. 7 is a schematic plan view illustrating the back-surface side of the second sealing member 6 seen through from the front-surface side.

The second sealing member 6 is a cuboidal substrate, including an AT-cut crystal plate, like the crystal vibrating plate 4 and the first sealing member 5.

As illustrated in FIG. 6, the second sealing member 6 has, on its front surface, the second junction pattern 61 for sealing purpose to be joined for sealing to the second junction pattern 404 for sealing purpose on the back surface of the crystal vibrating plate 4. This second junction pattern 61 is formed in a circular shape along the whole circumference of the second sealing member 6 and substantially along the outer peripheral edge of the second sealing member 6 except its four corners.

The second sealing member 6 has four through electrodes; first to fourth through electrodes 601 to 604, which are formed so as to penetrate through the front and back main surfaces of the second sealing member 6. In these through electrodes 601 to 604, inner wall surfaces of through holes are each coated with a metal film. Like the first to fourth through electrodes 411 to 414 of the crystal vibrating plate 4, the first to fourth through electrodes 601 to 604 are formed at positions in four corners of the second sealing member 6 rectangular in plan view. As illustrated in FIG. 6, junction patterns 611 to 614 for connecting purpose are formed around the through electrodes 601 to 604 at positions in four corners of the front surface of the second sealing member 6. The through electrodes 601 to 604 are electrically connected to the junction patterns 611 to 614 for connecting purpose.

At positions close to short sides of the second sealing member 6 and on the inner side of the circular second junction pattern 61, two junction patterns 621 and 622 for connecting purpose and two junction patterns 623 and 624 for connecting purpose; four junction patterns in total, are formed correspondingly to the junction patterns 451, 452 and 402 for connecting purpose on the back surface of the crystal vibrating plate 4.

To allow a pressing force to be equally applied at the time of junction bonding, the junction patterns 621, 622, 623 and 624 for connecting purpose on the front surface of the second sealing member 6 and the junction patterns 611 to 614 for connecting purpose formed at positions in four corners of the front surface are substantially symmetric in the directions along short and long sides of the second sealing member 6, like the crystal vibrating plate 4.

As illustrated in FIG. 7, the second sealing member 6 has, on its back surface, four terminals; first to fourth terminals 631 to 634 for external connection, which are used to mount the temperature-compensated crystal oscillator 1 to an external circuit board.

In the illustrated example, the first terminal 631 for external connection is a terminal to be connected to a power supply. The second terminal 632 for external connection is a terminal for oscillation output. The third terminal 633 for external connection is a terminal for control voltage input. The fourth terminal 634 for external connection is a terminal for grounding.

The first to fourth terminals 631 to 634 for external connection are formed at positions in four corners of the second sealing member 6 rectangular in plan view. The first to fourth through electrodes 601 to 604 are formed in the corner regions of the first to fourth terminals 631 to 634 for external connection and are thus electrically connected to the respective terminals 631 to 634 for external connection.

As with the first and second junction patterns 403 and 404 for sealing purpose of the crystal vibrating plate 4, the respective patterns and terminals of the second sealing member 6; the second junction pattern 61 for sealing purpose, junction patterns 611 to 614 and 621 to 624 for connecting purpose and first to fourth terminals 631 to 634 for external connection, are so structured that an Au layer is stacked on a ground layer including, for example, Ti or Cr.

Unlike the known art in which bonding materials, such as adhesives, may be used, the crystal vibrator 2 described in this embodiment is produced in the form of a multilayered package, as illustrated in FIG. 1, in which the crystal vibrating plate 4 and the first sealing member 5 are joined by diffusion bonding, with the first junction patterns 403 and 51 for sealing purpose being stacked on each other, and the crystal vibrating plate 4 and the second sealing member 6 are joined by diffusion bonding, with the second junction patterns 404 and 61 for sealing purpose being stacked on each other. In the package thus structured, the housing space in which the vibrating portion 41 of the crystal vibrating plate 4 is housed may be air-tightly sealed with the sealing members 5 and 6.

In this instance, the first junction pattern 403 for sealing purpose of the crystal vibrating plate 4 and the first junction pattern 51 for sealing purpose of the first sealing member 5 are combined by diffusion bonding into a bonding material, and the second junction pattern 404 for sealing purpose of the crystal vibrating plate 4 and the second junction pattern 61 for sealing purpose of the second sealing member 6 are combined by diffusion bonding into a bonding material.

By performing the diffusion bonding under pressure, bonding strengths of the respective bonding materials may be successfully improved.

At the time of the diffusion bonding, the junction patterns for connecting purpose described earlier are stacked on and joined to each other by the bonding materials generated by diffusion bonding.

Specifically, the junction patterns 421 to 424 for connecting purpose formed at positions in four corners of the front surface of the crystal vibrating plate 4 are joined by diffusion bonding to the junction patterns 511 to 514 for connecting purpose formed at positions in four corners of the back surface of the first sealing member 5. The junction patterns 441 and 442 for connecting purpose formed at positions on the front surface of the crystal vibrating plate 4 close to a short side thereof on the inner side of the circular first junction pattern 403 for sealing purpose are joined by diffusion bonding to the junction patterns 515 and 517 for connecting purpose on the back surface of the first sealing member 5. The junction patterns 425 and 401 for connecting purpose formed at positions on the front surface of the crystal vibrating plate 4 close to the other side thereof on the inner side of the circular first junction pattern 403 for sealing purpose are joined by diffusion bonding to the junction patterns 518 and 516 for connecting purpose on the back surface of the first sealing member 5.

Further, the junction patterns 431 to 434 for connecting purpose formed at positions in four corners of the back surface of the crystal vibrating plate 4 are joined by diffusion bonding to the junction patterns 611 to 614 on the front surface of the second sealing member 6. The junction patterns 451 and 452 for connecting purpose formed at positions on the back surface of the crystal vibrating plate 4 close to a short side thereof on the inner side of the circular second junction pattern 404 for sealing purpose are joined by diffusion bonding to the junction patterns 621 and 622 for connecting purpose on the front surface of the second sealing member 6. The junction pattern 402 for connecting purpose at a position on the back surface of the crystal vibrating plate 4 close to the other short side thereof on the inner side of the circular second junction pattern 404 for sealing purpose are joined by diffusion bonding to the junction patterns 623 and 624 for connecting purpose on the front surface of the second sealing member 6.

The junction patterns 611 to 614 for connecting purpose on the front surface of the second sealing member 6 and the junction patterns 431 to 434 for connecting purpose on the back surface of the crystal vibrating plate 4 are formed into bonding materials as a result of the diffusion bonding described above. Then, the first to fourth through electrodes 601 to 604 electrically connected, with these bonding materials, to the first to fourth terminals 631 to 634 for external connection on the back surface of the second sealing member 6 are electrically connected to the first to fourth through electrodes 411 to 414 of the crystal vibrating plate 4.

The junction patterns 421 to 424 for connecting purpose formed around the through electrodes 411 to 414 on the front surface of the crystal vibrating plate 4 and the junction patterns 511 to 514 for connecting purpose on the back surface of the first sealing member 5 are formed into bonding materials as a result of the diffusion bonding described above. The, the first to fourth through electrodes 411 to 414 of the crystal vibrating plate 4 are electrically connected, with these bonding materials, to the first to fourth through electrodes 501 to 504 of the first sealing member 5.

Therefore, the first to fourth terminals 631 to 634 for external connection on the back surface of the second sealing member 6 are electrically connected, respectively, to the first to fourth through electrodes 411 to 414 of the crystal vibrating plate 4 via the first to fourth through electrodes 601 to 604 of the second sealing member 6. These first to fourth terminals 631 to 634 for external connection are further electrically connected, respectively, to the first to fourth through electrodes 501 to 504 of the first sealing member 5 via the first to fourth through electrodes 411 to 414.

As illustrated in FIG. 4, the first to fourth through electrodes 411 to 414 of the first sealing member 5 are electrically connected, respectively, to the electrode connectors 546, 543, 544 and 541 of the sixth, third, fourth and first electrodes 526, 523, 524 and 521 for mounting purpose on the front surface of the first sealing member 5. Therefore, the first to fourth terminals 631 and 634 for external connection of the second sealing member 6 are electrically connected, respectively, to the electrode connectors 546, 543, 544 and 541 of the sixth, third, fourth and first electrodes 526, 523, 524 and 521 for mounting purpose on the front surface of the first sealing member 5.

The junction pattern 401 for connecting purpose, which is connected to the first driving electrode 45 on the front surface of the crystal vibrating plate 4 illustrated in FIG. 2 through the first extraction electrode 47, is electrically connected to the sixth through electrode 506 of the first sealing member 5 with the bonding material generated by the diffusion bonding of the junction pattern 516 for connecting purpose formed around the sixth through electrode 506 on the back surface of the first sealing member 5 illustrated in FIG. 5. As illustrated in FIG. 4, the sixth through electrode 506 of the first sealing member 5 is electrically connected to the fifth electrode connector 545 of the fifth electrode 525 for mounting purpose on the front surface of the first sealing member 5. The first driving electrode 45 of the crystal vibrating plate 4 is, therefore, electrically connected to the fifth electrode connector 545 of the fifth electrode 525 for mounting purpose of the first sealing member 5 via the sixth through electrode 506 of the first sealing member 5.

The fifth through electrode 415 electrically connected to the second driving electrode 46 on the back surface of the crystal vibrating plate 4 illustrated in FIG. 3 through the second extraction electrode 48 and the junction pattern 402 for connecting purpose is also electrically connected to the junction pattern 425 for connecting purpose on the front surface of the crystal vibrating plate 4 illustrated in FIG. 2. The fifth through electrode 415 of the crystal vibrating plate 4 is electrically connected, with the bonding material generated by the diffusion bonding of the junction pattern 425 for connecting purpose of the crystal vibrating plate 4 and the junction pattern 518 for connecting purpose on the back surface of the first sealing member 5 illustrated in FIG. 5, to the junction pattern 518 for connecting purpose on the back surface of the first sealing member 5. The junction pattern 518 for connecting purpose on the back surface of the first sealing member 5 is connected to the junction pattern 515 for connecting purpose formed around the fifth through electrode 505 through the wiring pattern 519 for connecting purpose. The junction pattern 516 for connecting purpose on the back surface of the first sealing member 5 is electrically connected to the fifth through electrode 505. As illustrated in FIG. 4, the fifth through electrode 505 is electrically connected to the second electrode connector 542 of the second electrode 522 for mounting purpose on the front surface of the first sealing member 5.

The second driving electrode 46 on the back surface of the crystal vibrating plate 4 is, therefore, electrically connected to the second electrode connector 542 of the second electrode 522 for mounting purpose on the front surface of the first sealing member 5 via the fifth through electrode 415 of the crystal vibrating plate 4, junction patterns 518, 519 and 515 for connecting purpose on the back surface of the first sealing member 5, and the fifth through electrode 505 of the first sealing member 5.

In the surface-mounted, temperature-compensated crystal oscillator 1 thus characterized, the first to fourth terminals 631 to 634 for external connection of the second sealing member 6 on the back surface of the crystal vibrator 2 are, as illustrated in FIG. 1, mounted and joined with a bonding material, such as solder, to an external circuit board not illustrated in the drawing.

In case the external circuit board is mounted with any electronic components (for example, IC and/or power transistors) which is a heat source, such electronic components, when turned on, may start to generate heat very fast, which may be transferred to the surface-mounted, temperature-compensated crystal oscillator 1 mounted to the external circuit board.

The heat from the external circuit board may be then transferred to the vibrating portion 41 of the crystal vibrating plate 4 in the crystal vibrator 2 via the first to fourth terminals 631 to 634 for external connection and the first to fourth through electrodes 601 to 604 on the back-surface side of the crystal vibrator 2 of the surface-mounted, temperature-compensated crystal oscillator 1. As a result, the temperature of the crystal vibrating plate 4 may be elevated to higher degrees.

In the IC3 mounted on the first sealing member 5 on the front-surface side of the crystal vibrator 2, on the other hand, any heat from the external circuit board may be transferred through the three-layered crystal vibrator 2. This may slow down the rate of temperature rise, as compared with the vibrating portion 41 of the crystal vibrating plate 4.

Then, temperature differences may occur between the vibrating portion 41 of the crystal vibrating plate 4 and the temperature sensor 301 embedded in the IC3, and accurate temperature compensation may be difficult to perform, causing frequency variations until the vibrating portion 41 of the crystal vibrating plate 4 and the temperature sensor 301 of the IC3 can reach the state of thermal equilibrium with no temperature difference between them.

This embodiment provides the following technical features in order to control such temperature differences between the vibrating portion 41 of the crystal vibrating plate 4 and the temperature sensor 301 embedded in the IC3 and to allow the state of thermal equilibrium to be achieved fast between the vibrating portion 41 of the crystal vibrating plate 4 and the temperature sensor 301 of the IC3.

As illustrated in FIG. 4, the first to sixth mounting terminals 31 to 36 of the IC3 are arranged at positions close to the outer circumference of the IC3 rectangular in plan view. Specifically, the first to sixth mounting terminals 31 to 36 are located at positions close to a pair of long sides among two pairs of opposing sides of the rectangular shape and are arranged in two rows along the long sides. The pair of opposing sides may be “short sides” instead of the “long sides”.

In this embodiment, of the first to sixth electrodes 521 to 526 for mounting purpose formed on the front surface of the first sealing member 5, the first and sixth electrodes 521 and 526 for mounting purpose respectively have a first wiring pattern 561 and a sixth wiring pattern 566 extending inward in the mounting region S rectangular in plan view where the IC3 is mounted.

The first wiring pattern 561 electrically connects the first terminal junction 531, which is joined to the first mounting terminal 31 of the IC3, to the first electrode connector 541 connected to the fourth through electrode 504. As described earlier, the fourth through electrode 504 is electrically connected to the fourth terminal 634 for external connection via the fourth through electrode 414 of the crystal vibrating plate 4 and the fourth through electrode 604 of the second sealing member 6.

The second wiring pattern 566 electrically connects the sixth terminal junction 536, which is joined to the sixth mounting terminal 36 of the IC3, to the sixth electrode connector 546 connected to the first through electrode 501. As described earlier, the first through electrode 501 is connected to the first terminal 631 for external connection via the first through electrode 411 of the crystal vibrating plate 4 and the first through electrode 601 of the second sealing member 6.

Thus, heat from the external circuit board is transferred to the first wiring pattern 561 made of an electrically conductive material via the fourth terminal 634 for external connection and the fourth through electrodes 604, 414 and 504. The heat from the external circuit board is also transferred to the second wiring pattern 566 made of an electrically conductive material via the first terminal 631 for external connection and the first through electrodes 601, 411 and 501.

In the rectangular mounting region S mounted with the IC3, the first and sixth wiring patterns 561 and 566 subjected to the heat transferred from the external circuit board are formed so as to extend through center and near-center parts of the mounting region S and diagonally traverse an interval between the first to third mounting terminals 31 to 33 and the fourth to sixth mounting terminals 35 to 36 that are arranged in two rows.

The six wiring pattern 566, in particular, is extending so as to exactly overlap with a rectangular region of projection where the temperature sensor 301 of the IC3 is projected in the mounting region S.

As described, heat from the external circuit board is transferred to the first wiring pattern 561 and the second wiring pattern 566 via the terminals 634 and 631 for external connection and the through electrodes 604, 414 and 504, and 601, 411 501, and the first wiring pattern 561 and the sixth wiring pattern 566 are formed so as to extend and diagonally traverse the mounting region S of the IC3. Then, the IC3 mounted in the mounting region S may be heated to higher temperatures by the heat transferred from the external circuit board mounted with the temperature-compensated crystal oscillator 1 to the first and six wiring patterns 561 and 566. The IC3 lower in temperature than the crystal vibrating plate 4 may be thus elevated to higher temperatures, so that possible temperature differences to the crystal vibrating plate 4 may be controlled to allow the state of thermal equilibrium between the crystal vibrating plate 4 and the IC3. This may successfully control possible frequency variations caused by differences between temperatures of the crystal oscillator 2 and of the temperature sensor 301 in the IC3, conducing to accurate temperature compensation.

In this embodiment, the first wiring pattern 561 and the six wiring pattern 566 are respectively connected to the fourth grounding-use terminal 634 for external connection and the first power-use terminal 631 for external connection. The temperature of the 13 may be thus efficiently elevated, and the state of thermal equilibrium may be achieved fast between the IC3 and the crystal vibrating plate 4.

The six wiring pattern 566 is formed so as to entirely include the region of projection of the temperature sensor 301 embedded in the IC3. Therefore, the temperature sensor 301 used to detect temperatures for temperature compensation may be efficiently heated by the heat transferred to the six wiring pattern 566, and the crystal vibrating plate 4 and the IC3 may rapidly reach the state of thermal equilibrium.

In this embodiment, the crystal vibrator 2 has a thin three-layered structure including AT-cut crystal plates; the crystal vibrating plate 4 and the first and second sealing members 5 and 6. Further, the crystal vibrator 2 is better in thermal conduction than crystal vibrators of the known art equipped with ceramic-made containers having large thermal capacities for housing crystal vibrating pieces. These advantageous features may allow possible temperature differences between the crystal vibrator 2 and the IC3 to be more effectively controlled.

In this embodiment, the IC3 rectangular in plan view is mounted on the first sealing member 5 rectangular in plan view in a manner long sides of the IC3 are along short sides of the first sealing member 5, as illustrated in FIG. 4. The underfill resin 8, therefore, may be easily injected through long sides of the IC3 into between the IC3 and the first sealing member 5. Also, parts of the first to sixth electrodes 521 to 526 for mounting purpose extending beyond the mounting region S of the IC3 may be covered with the underfill resin 8.

In the first and sixth electrodes 521 and 526 for mounting purpose described in this embodiment, the first and sixth terminal junctions 531 and 536 and the first and six electrode connectors 541 and 546 are spaced apart from each other and are electrically connected through the first and sixth wiring patterns 561 and 566.

The terminal junctions and the electrode connectors of the electrodes for mounting purpose may be arranged in proximity and electrically connected to each other without the wiring patterns being used for electrical connection, so that the IC3 is heated by thermal conduction alone. In this instance, the first and sixth wiring patterns 561 and 566 of this embodiment are not necessarily formed so as to extend and diagonally traverse an interval between the first to third mounting terminals 31 to 33 and the fourth to six mounting terminals 36 to 36 that are arranged in two rows. For example, the first and sixth wiring patterns 561 and 566 may be formed so as to extend to an intermediate position between two rows of the first to third mounting terminals 31 to 33 and the fourth to six mounting terminals 35 to 36.

In this embodiment, the two electrodes 521 and 526 for mounting purpose have the first and sixth wiring patterns 561 and 566 extending inward in the mounting region S of the IC3. Instead, at least one of these electrodes for mounting purpose may have a wiring pattern extending inward in the mounting region S of the IC3.

Preferably, the terminals for external connection connected to the electrodes for mounting purpose having the wiring patterns may be electrically connected to the electronic components; heat source, mounted on the external circuit board mounted with the temperature-compensated crystal oscillator.

In this preferred example, the heat from the electronic components; heat source, of the external circuit board may be efficiently transferred to the wiring patterns of the electrodes for mounting purpose, and the IC may be rapidly heated to higher temperatures.

The wiring patterns are not necessarily formed in any particular shapes. For example, the wiring patterns may be so shaped as to branch off and extend.

In the embodiment described above, the IC3 is mounted on the first sealing member 5 on the front-surface side of the crystal vibrator 2. Instead, the IC3 may be mounted on the second sealing member 6 on the back-surface side of the crystal vibrator 2.

The embodiment described so far may be advantageous for effective control of any temperature differences between the IC and the crystal vibrator heated to higher temperatures than the IC, allowing the state of thermal equilibrium to be achieved fast between the IC and the crystal vibrator.

In contrast to what has been described so far, the IC driven to operate may start to generate heat, reaching higher temperatures than the crystal vibrator. Next is described a temperature-compensated crystal oscillator according to another invention in which such temperature differences between the IC and the crystal vibrator are desirably controllable for the state of thermal equilibrium to be rapidly reached. The invention according to the earlier embodiment illustrated in FIGS. 1 to 7 is referred to as “main invention” to distinguish this invention from the invention hereinafter described.

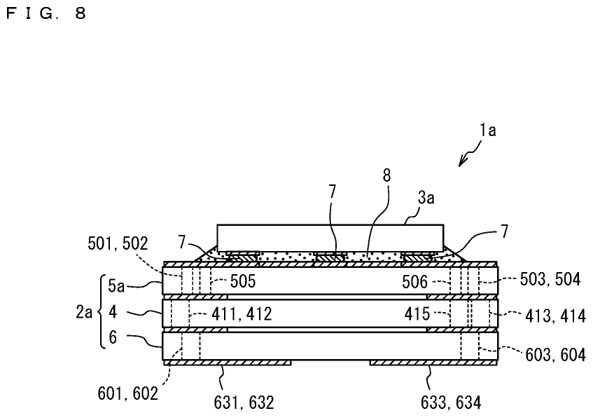

FIG. 8 is a schematic structural view of a temperature-compensated crystal oscillator according to an embodiment of another invention, which is illustrated correspondingly to FIG. 1. Any components identical or similar to those of the embodiment of FIG. 1 are illustrated with the same or similar reference signs.

A temperature-compensated crystal oscillator 1a according to an embodiment of the invention hereinafter described includes a crystal oscillator 2a and an IC3a; integrated circuit element, mounted on the crystal vibrator 2a.

The crystal vibrator 2a includes a crystal vibrating plate 4, a first sealing member 5a that covers and air-tightly seals one main-surface side of the crystal vibrating plate 4, and a second sealing member 6 that covers and air-tightly seals the other main-surface side of the crystal vibrating plate 4.

In a manner similar to the embodiment of the main invention, the crystal vibrator 2 is produced in the form of a multilayered package in which the first and second sealing members 5a and 6 are respectively joined to one and the other main surfaces of the crystal vibrating plate 4.

The IC3a mounted on the crystal vibrator 2a is an integrated circuit element having a cuboidal outer shape in which an oscillator circuit, a temperature sensor and a temperature-compensated circuit are combined into one chip.

Next are described structural features of the crystal vibrating plate 4 and of the first and second sealing members 5a and 6 constituting the crystal vibrator 2a.

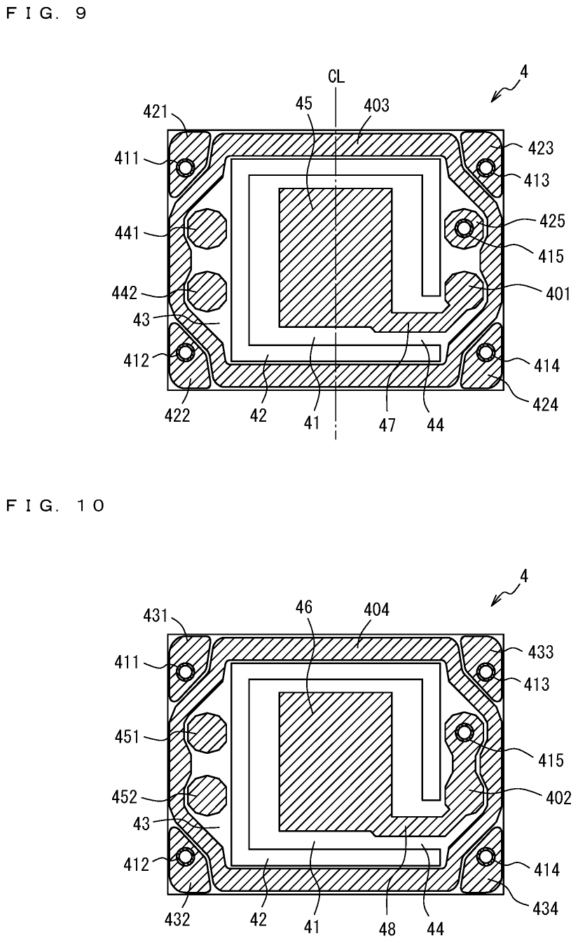

FIG. 9 is a schematic plan view illustrating one main-surface side of the crystal vibrating plate 4. FIG. 10 is a schematic plan view illustrating the other main-surface side of the crystal vibrating plate 4 seen through from the one main-surface side.

As illustrated in FIGS. 9 and 10, the crystal vibrating plate 4 is structured similarly to the illustrations of FIGS. 2 and 3 according to the embodiment of the main invention and will not be described in detail again.

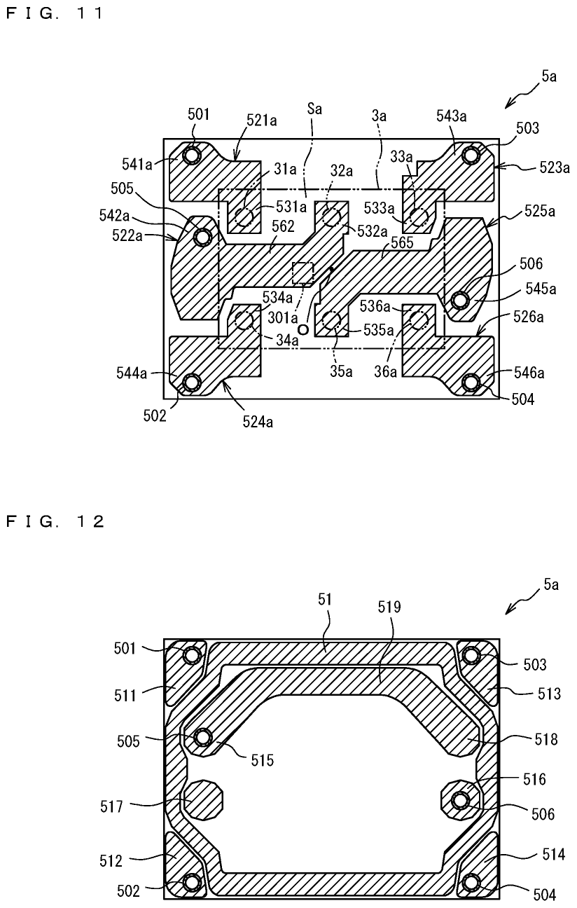

FIG. 11 is a schematic plan view illustrating the front-surface side of the first sealing member 5a. FIG. 12 is a schematic plan view illustrating the back-surface side of the first sealing member 5a seen through from the front-surface side.

As illustrated in FIG. 12, the front-surface side of the first sealing member 5a is structured similarly to the illustration of FIG. 5 according to the embodiment of the main invention and will not be described in detail again.

As with the embodiment of the main invention, the first sealing member 5a is a cuboidal substrate including an AT-cut crystal plate similar to the crystal vibrating plate 4.

The first sealing member 5a includes six through electrodes; first to sixth through electrodes 501 to 506, which are formed so as to penetrate through the front and back main surfaces of the first sealing member 5a.

The front surface of the first sealing member 5a is a surface to be mounted with the IC3a. In FIG. 1 showing the front surface of the first sealing member 5a, virtual lines are used to illustrate the rectangular outer shape of the IC3a in plan view mounted on the first sealing member 5a and outer shapes of first to sixth mounting terminals 31a to 36a of the IC3a and a temperature sensor 301a embedded in the IC3a.

As illustrated in FIG. 11, the first sealing member 5a has, on its front surface, first to sixth electrodes 521a to 526a for mounting purpose. The first to sixth mounting terminals 31a to 36a of the IC3a are respectively connected to these electrodes 521a to 526a for mounting purpose.

In a rectangular mounting region Sa defined with a virtual line where the IC3a is mounted, the first to sixth electrodes 521a to 526a for mounting purpose have first to sixth terminal junctions 531a to 536a including electrode pads (not illustrated in the drawings) to which the mounting terminals 31a to 36a of the IC3a are connectable. The first to sixth electrodes 521a to 526a for mounting purpose further have first to sixth electrode connectors 541a to 546a electrically connectable to the through electrodes, 501, 505, 503, 502, 506 and 504. These electrode connectors 541a to 546a extend from the first to sixth terminal junctions 531a to 536a in the mounting region Sa toward the outside of the mounting region Sa.

As illustrated in FIG. 8, the IC3a is joined, with a metallic member; metal bumps 7 (for example, Au bumps), to the front surface of the first sealing member 5a by the FCB (flip-chip bonding). Instead of the metal bumps 7, metal plating or metal paste may be used for bonding.

An interval between the IC3a and the first sealing member 5a is filled with a sealing resin; underfill resin 8, to protect the acting surface of the IC3a and to ensure a mechanical bonding strength required.

The other structural features of the first sealing member 5a will be described later.

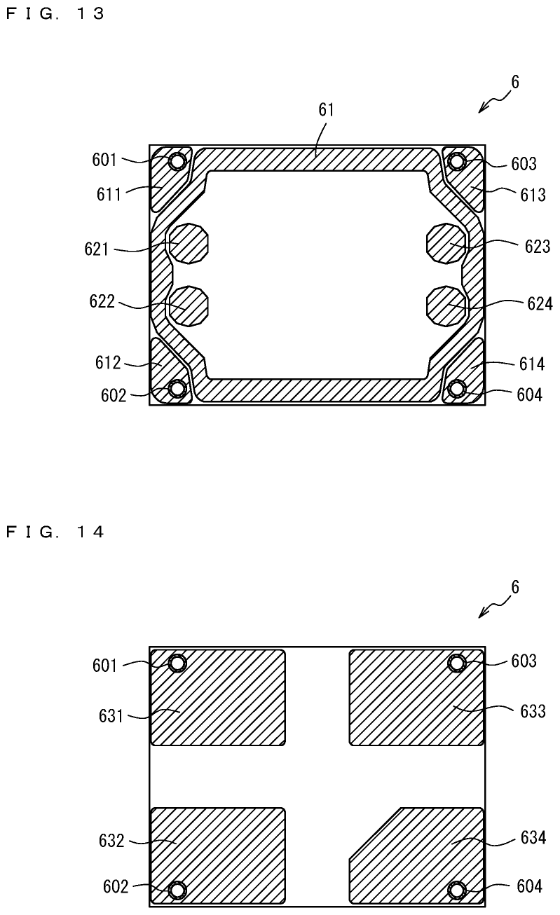

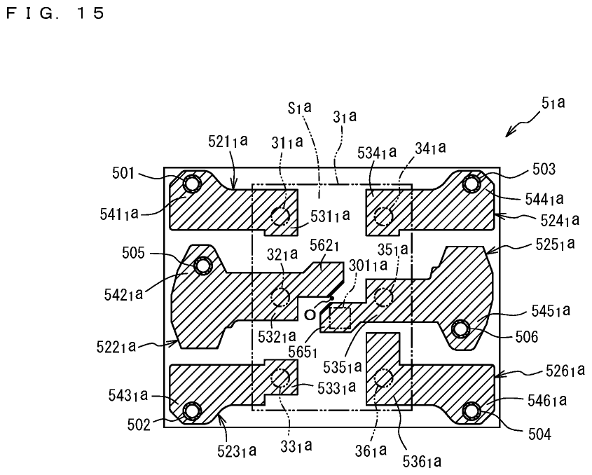

FIG. 13 is a schematic plan view illustrating the front-surface side of the second sealing member 6. FIG. 14 is a schematic plan view illustrating the back-surface side of the second sealing member 6 seen through from the front-surface side.

As illustrated in FIGS. 13 and 14, the second sealing member 6 is structured similarly to the illustrations of FIGS. 6 and 7 according to the embodiment of the main invention and will not be described in detail again.

In this embodiment, the back surface of the first sealing member 5a, crystal vibrating plate 4 and second sealing member 6 are so structured as described in the embodiment of the main invention. The first sealing member 5a, crystal vibrating plate 4 and second sealing member 6 are stacked on and joined to one another by diffusion bonding. Detailed bonding mechanisms between the crystal vibrating plate 4 and the back surface of the first sealing member 5a and between the crystal vibrating plate 4 and the second sealing member 6 are the same as described in the embodiment of the main invention.

Referring to FIG. 11, the first to fourth thorough electrodes 501 to 504 of the first sealing member 5a are electrically connected to the electrode connectors 541a, 544a, 543a and 546a of the first, fourth, third and sixth electrodes 521a, 524a, 523a and 546a for mounting purpose on the front surface of the first sealing member 5a. Thus, the first to fourth terminals 631 to 634 for external connection on the back surface of the second sealing member 6 are electrically connected to the electrode connectors 541a, 544a, 543a and 546a of the first, fourth, third and sixth electrodes 521a, 524a, 523a and 546a for mounting purpose on the front surface of the first sealing member 5.

In a manner similar to the embodiment of the main invention, the sixth through electrode 506 of the first sealing member 5a electrically connected to the first driving electrode 45 of the crystal vibrating plate 4 is electrically connected to the fifth electrode connector 545a of the fifth electrode 525a for mounting purpose. The first driving electrode 45 of the crystal vibrating plate 4 is, therefore, electrically connected to the fifth electrode connector 545a of the fifth electrode 525a for mounting purpose of the first sealing member 5a via the sixth through electrode 506 of the first sealing member 5a.

In a manner similar to the embodiment of the main invention, the fifth through electrode 505 of the first sealing member 5a electrically connected to the second driving electrode 46 of the crystal vibrating plate 4 is electrically connected to the second electrode connector 542a of the second electrode 522a for mounting purpose. The second driving electrode 46 on the back surface of the crystal vibrating plate 4 is, therefore, electrically connected to the second electrode connector 542a of the second electrode 522a for mounting purpose on the front surface of the first sealing member 5a via the fifth through electrode 505 of the first sealing member 5a.

In the surface-mounted, temperature-compensated crystal oscillator 1a thus characterized, the first to fourth terminals 631 to 634 for external connection of the second sealing member 6 on the back-surface side of the crystal vibrator 2a are, as illustrated in FIG. 8, mounted and joined with a bonding material, such as solder, to an external circuit board not illustrated in the drawing.

In the surface-mounted, temperature-compensated crystal oscillator 1a thus characterized, the IC3a, when driven to operate, may start to generate heat, rapidly reaching higher temperatures. This may invite temperature differences between the IC3a and the crystal vibrator 2a. Then, the temperature sensor 301a embedded in the IC3a may fail to accurately detect the temperature of the crystal vibrator 2a. As a result, accurate temperature compensation of the crystal vibrator 2a may not be possible, causing frequency variations until the IC3a and the crystal vibrator 2a can reach the state of thermal equilibrium with no temperature difference between them.

Possible temperature differences between the IC3a and the crystal vibrator 2a do not necessarily result from the startup of the IC3a, and may occur likewise when, for example, the temperature of the crystal vibrator 2a close to the external circuit board drops faster than the IC3a that has been turned off.

This embodiment provides the following technical features in order to control such temperature differences between the IC3a and the crystal vibrator 2a resulting from heat generated by the startup of the IC3a and to allow the IC3a and the crystal vibrator 2a to reach the state of thermal equilibrium.

As illustrated in FIG. 11, the first to sixth mounting terminals 31a to 36a of the IC3a are arranged at positions close to the outer circumference of the IC3a rectangular in plan view. Specifically, the first to sixth mounting terminals 31a to 36a are located at positions close to a pair of long sides among two pairs of opposing sides of the rectangular shape and are arranged in two rows along the long sides. The pair of opposing sides may be “short sides” instead of the “long sides”.

In this embodiment, of the first to sixth electrodes 521a to 526a for mounting purpose formed on the front surface of the first sealing member 5a, the second and fifth electrodes 522a and 525a that are formed in a pair and respectively connected to the driving electrodes 46 and 45 of the crystal vibrating plate 4 have a second wiring pattern 562 and a fifth wiring pattern 565 extending inward in the mounting region Sa rectangular in plan view where the IC3a is mounted. The wiring patterns 562 and 565 are formed in a large width, so that areas of these wiring patterns facing the IC3a in the mounting region Sa are adequately large.

In the rectangular mounting region Sa, the second and fifth wiring patterns 562 and 565 are extending along long sides of the IC3a between the first to third mounting terminals 31a to 33a and the fourth to sixth mounting terminals 34a to 36a of the IC3a that are arranged in two rows, and then bend diagonally at a near-center position and further extend toward the second and fifth mounting terminals 32a and 35an. The second wiring pattern 562 is extending so as to exactly overlap with a rectangular region of projection where the temperature sensor 301a of the IC3a is projected in the mounting region Sa.

The second and fifth wiring patterns 562 and 565 large in width of the paired second and fifth electrodes 522a and 525a for mounting purpose respectively connected to the driving electrodes 46 and 45 of the crystal vibrating plate 4 are formed so as to face the IC3a in the mounting region Sa of the IC3a.

When the IC3a is driven to operate and generates heat, the temperature of the IC3a may rapidly increase to higher degrees than the crystal vibrator 2a, causing temperature differences between the IC3a and the crystal vibrator 2a. In that event, heat released from the IC3a may heat the second and fifth wiring patterns 562 and 565 disposed immediately below and facing the IC3a.

The second and fifth wiring patterns 562 and 565 are extending from the electrode connectors 542a and 545a of the second and fifth electrodes 522a and 525a for mounting purpose. The electrode connectors 542a and 545a are electrically connected to the fifth and sixth through electrodes 505 and 506. The fifth through electrode 505 is connected to the second driving electrode 46 on the back surface of the crystal vibrating plate 4. The sixth through electrode 506 is connected to the first driving electrode 45 on the front surface of the crystal vibrating plate 4.

The second and fifth wiring patterns 562 and 565 are thus connected to the driving electrodes 46 and 45 of the crystal vibrating plate 4. After the wiring patterns 562 and 565 are heated by the heat release from the IC3a at high temperatures, heat from these heated wiring patterns 562 and 565 is possibly transferred to the driving electrodes 46 and 45 of the crystal vibrating plate 4. As a result, the temperature of the crystal vibrating plate 4 may be elevated to higher degrees.

The IC3a at higher temperatures than the crystal vibrator 2a releases heat, dropping to lower temperatures. On the other hand, the crystal vibrator 2a is increased in temperature by the heat transferred from the second and fifth wiring patterns 562 and 565 heated by the heat release from the IC3a. Thus, possible temperature differences may be dissipated between the IC3a and the crystal vibrator 2a. As a result, the IC3a and the crystal vibrator 2a may rapidly reach the state of thermal equilibrium.

This may successfully control frequency variations that result from differences between the detected temperature of the temperature sensor 301a of the IC3a and the temperature of the crystal vibrator 2a, conducing to accurate temperature compensation.

In this embodiment, the second electrode 522a for mounting purpose having the second wiring pattern 562 and the fifth electrode 525a for mounting purpose having the fifth wiring pattern 565 are formed in a manner that their wiring patterns are point-symmetric with respect to a point of center O of the mounting region Sa rectangular in plan view. By having the second and fifth wiring patterns 562 and 565 thus symmetrically formed, heat released from the IC3a at high temperatures may be received by these wiring patterns in a well-balanced manner, and the second and fifth wiring patterns 562 and 565 may be thus efficiently heated.

In this embodiment, the second wiring pattern 562 is formed so as to entirely include the region of projection of the temperature sensor 301a embedded in the IC3a. The second wiring pattern 562 immediately below and facing the IC3a is heated by the heat released from the temperature sensor 301a of the IC3a, and the heat from the second wiring pattern 562 is transferred to the crystal vibrating plate 4 of the crystal vibrator 2a. This may allow the state of thermal equilibrium to be achieved fast between the crystal vibrating plate 4 and the temperature sensor 301a of the IC3a, conducing to accurate temperature compensation.

Any other structural and technical features and effects of this embodiment are similar to those achieved by the embodiment of the main invention.

FIG. 15 is a schematic view illustrating the front-surface side of a first sealing member 5₁a in a crystal vibrator of a temperature-compensated crystal oscillator according to another embodiment of the another invention.

All of the structural and technical features in this embodiment but electrode patterns on front surfaces of the first sealing member 5₁a and of an IC3₁a, i.e., the back-surface side of the first sealing member 5₁a, crystal vibrating plate 4 and second sealing member 6, are similar to those described in the embodiment illustrated in FIGS. 9, 10 and 12 to 14 and will not be described in detail again.

In this embodiment, a direction in which the IC3₁a is mounted on the first sealing member 5₁a differs from what is described in the earlier embodiment, and electrode patterns of the first sealing member IC3₁a accordingly differ from what is described in the earlier embodiment. In the earlier embodiment, the IC3a is mounted on the first sealing member 5a in a manner that long sides of the IC3a extend along long sides of the first sealing member 5a, as illustrated in FIG. 11. In this embodiment, the IC3₁a is mounted on the first sealing member 5₁a in a manner that long sides of the IC3₁a are orthogonal to long sides of the first sealing member 5₁a, as illustrated in FIG. 15.

On the front surface of the first sealing member 5₁a are formed first to sixth electrodes 521₁a to 526₁a for mounting purpose to which first to sixth mounting terminals 31₁a to 36₁a of the IC3₁a are connected correspondingly to the arrangement of these first to sixth mounting terminals 31₁a to 36₁a.

In a rectangular mounting region 5₁a defined with a virtual line where the IC3₁a is mounted, the first to sixth electrodes 521₁a to 526₁a for mounting purpose have first to sixth terminal junctions 531₁a to 536₁a including electrode pads (not illustrated in the drawings) to which the mounting terminals 31₁a to 36₁a of the IC3₁a are respectively connected. The first to sixth electrodes 521₁a to 526₁a further have first to sixth electrode connectors 5411a to 5461a extending beyond the mounting region 5₁a from the first to sixth terminal junctions 531₁a to 536₁a of the mounting region 5₁a and electrically connected, respectively, to the through electrodes 501, 505, 502, 503, 506 and 504.

In this embodiment, of the first to sixth electrodes 521₁a to 526₁a for mounting purpose formed on the front surface of the first sealing member 5₁a, the second and fifth electrodes 521₁a and 525₁a for mounting purpose that are formed in a pair and respectively connected to the driving electrodes 46 and 45 of the crystal vibrating plate 4 have a second wiring pattern 562₁ and a fifth wiring pattern 565₁ extending inward in the mounting region 5₁a rectangular in plan view where the IC3₁a is mounted.

In the rectangular mounting region 5₁a mounted with the IC3₁a, the second and fifth wiring patterns 562₁ and 565₁ are extending as far as an interval between the first to third mounting terminals 31₁a to 33₁a and the fourth to sixth mounting terminals 34₁a to 36₁a that are arranged in two rows.

The fifth wiring patterns 565₁, in particular, is extending so as to exactly overlap with the rectangular region of projection of the mounting region 5₁a.

In the earlier embodiment, the second and fifth electrode connectors 542a and 545a and the second and fifth terminal junctions 532a and 535a of the second and fifth electrodes 522a and 525a for mounting purpose are spaced apart from each other and are electrically connected through the second and fifth wiring patterns 562 and 565.

In this embodiment, on the other hand, the second and fifth electrode connectors 542₁a and 545₁a and the second and fifth terminal junctions 532₁a and 535₁a for mounting purpose of the second and fifth electrodes 522₁a and 525₁a for mounting purpose are arranged in proximity and electrically connected. Thus, the second and fifth wiring patterns 562₁ and 565₁ solely functions as thermal conductors, without providing electrical connection between the second and fifth electrode connectors 542₁a and 545₁a and the second and fifth terminal junctions 532₁a and 535₁a.

In this embodiment, the second electrode 522₁a for mounting purpose having the second wiring pattern 562₁ and the fifth electrode 525₁a for mounting purpose having the fifth wiring pattern 565₁ are formed in a manner that their wiring patterns are point-symmetric with respect to a point of center O of the mounting region S rectangular in plan view.

In this embodiment, the second and fifth wiring patterns 562₁ and 565₁ are respectively connected to the driving electrodes 46 and 45 of the crystal vibrating plate 4. When the second and fifth wiring patterns 562₁ and 565₁ are heated by the heat release from the IC3₁a which are turned on and heated to higher temperatures than the crystal vibrating plate 4, heat from the second and fifth wiring patterns 562₁ and 565₁ thus heated is then transferred to and heat the driving electrodes 46 and 45 of the crystal vibrating plate 4.

The heated IC3₁a releases heat, dropping to lower temperatures. On the other hand, the crystal vibrator 2a is increased in temperature under the heat transferred from the second and fifth wiring patterns 562₁ and 565₁ heated by the heat release from the IC3₁a. Thus, possible temperature differences may be dissipated between the IC3₁a and the crystal vibrator 2a. As a result, the IC3₁a and the crystal vibrator 2a may rapidly reach the state of thermal equilibrium.

This may successfully control frequency variations that result from differences between the detected temperature of the temperature sensor 301₁a of the IC3₁a and the temperature of the crystal vibrating plate 4, conducing to accurate temperature compensation.

In this embodiment, the IC3₁ rectangular in plan view is mounted on the first sealing member 5₁a rectangular in plan view in a manner that long sides of the IC3₁ extend along short sides of the first sealing member 5₁a, as illustrated in FIG. 15. The underfill resin 8, therefore, may be easily injected through long sides of the IC3₁ into between the IC3₁ and the first sealing member 5₁a. Also, parts of the first to sixth electrodes 521₁a to 526₁a for mounting purpose extending beyond the mounting region 5₁a of the IC3₁ may be covered with the underfill resin 8.

In the embodiments described thus far, the paired electrodes for mounting purpose, 522a and 525a, 522₁a and 525₁a have the wiring patterns 562 and 565, 562₁ and 565₁ extending inward in the mounting region Sa, 5₁a of the IC3a, IC3₁a. Instead, it may be at least one of these electrodes for mounting purpose that has a wiring pattern extending inward in the mounting region Sa, 5₁a of the IC3a, IC3₁a.

The wiring patterns are not necessarily formed in any particular shapes. For example, the wiring patterns may be so shaped as to branch off and extend.

In the embodiment described above, the IC3a, IC3₁a is mounted on the first sealing member 5a, 5₁a on the front-surface side of the crystal vibrator 2. The IC3a, IC3₁a may be mounted on the second sealing member 6 on the back-surface side of the crystal vibrator 2.

The structural and technical features and effects according to the embodiment of the another invention are hereinafter described.

The piezoelectric vibration device according to the another invention includes:

a piezoelectric vibrator including a plurality of terminals for external connection and a plurality of electrodes for mounting purpose; and

an integrated circuit element including a plurality of mounting terminals connectable to the plurality of electrodes for mounting purpose, the integrated circuit element being mountable to the piezoelectric vibrator.

The piezoelectric vibration device is further characterized in that

the piezoelectric vibrator includes:

a piezoelectric vibrating plate including driving electrodes formed on main surfaces on both sides thereof;

a first sealing member allowed to cover and seal one of the main surfaces of the piezoelectric vibrating plate; and

a second sealing member allowed to cover and seal the other one of the main surfaces of the piezoelectric vibrating plate,

a pair of electrodes for mounting purpose among the plurality of electrodes for mounting purpose are electrically connected to the driving electrodes formed on the main surfaces of the piezoelectric vibrating plate,

the plurality of mounting terminals in the integrated circuit element are formed at positions close to an outer circumference, and

at least one of the pair of electrodes for mounting purpose has a wiring pattern extending more inward in a mounting region where the integrated circuit element is mounted than at least the plurality of mounting terminals.

According to the another invention, at least one of the pair of electrodes for mounting purpose electrically connected to the driving electrodes on the main surfaces of the piezoelectric vibrating plate has a wiring pattern extending more inward in the mounting region than at least the mounting terminals in the mounting region of the integrated circuit element. In the piezoelectric vibration device thus characterized, the wiring pattern is facing the mounted integrated circuit.

When the integrated circuit element is driven to operate, generating heat, and is accordingly heated to higher temperatures than the piezoelectric vibrator, heat released from the integrated circuit element heats the wiring pattern facing this integrated circuit element. Since this wiring pattern is electrically connected to the driving electrode of the piezoelectric vibrator, heat from the wiring pattern thus heated is transferred to the piezoelectric vibrator lower in temperature than the integrated circuit element, by which the piezoelectric vibrator may be heated to higher temperatures. While the driven and heated integrated circuit element thus releases heat, dropping to lower temperatures, heat from the wiring pattern heated by this heat release is transferred to the piezoelectric vibrator, by which the piezoelectric vibrator may be heated to higher temperatures This may control possible temperature differences between the piezoelectric vibrator and the driven and heated integrated circuit element, allowing the integrated circuit element and the piezoelectric vibrator to rapidly reach the state of thermal equilibrium.

The piezoelectric vibrator has a multilayered structure including three layers; the piezoelectric vibrating plate having main surfaces on which the driving electrodes are formed, and the first and second sealing members covering and sealing the main surfaces. The piezoelectric vibrator thus structured may be advantageously reduced in thickness (reduced in height) as compared with, for example, such a packaging structure that piezoelectric vibration pieces are housed in the housing space of a container and sealed with a lid member.

The pair of electrodes for mounting purpose may each have a wiring pattern extending more inward in the mounting region of the integrated circuit element than at least the plurality of mounting terminals.

In the piezoelectric vibrator in which the paired electrodes for mounting purpose electrically connected to the main surfaces of the piezoelectric vibrating plate both have the wiring pattern extending more inward in the mounting region of the integrated circuit element than the mounting terminals, heat may be more efficiently transferred to the piezoelectric vibrator from the wiring patterns when these wiring patterns are heated by the heat release from the integrated circuit element driven and heated to higher temperatures than the piezoelectric vibrator. This may more rapidly control possible temperature differences between the piezoelectric vibrator and the driven and heated integrated circuit element, further accelerating the arrival of thermal equilibrium.

The wiring patterns of the pair of electrodes for mounting purpose may be substantially point-symmetric with respect to a point of center of the mounting region of the integrated circuit element.

By thus forming the wiring patterns of the paired electrodes for mounting purpose to be substantially point-symmetric with respect to the point of center of the mounting region, these wiring patterns may be equally heated by the heat released from the integrated circuit element, and the heat from the wiring patterns thus equally heated may be transferred to the main surfaces of the piezoelectric vibrating plate. As a result, the main surfaces of the piezoelectric vibrating plate may be heated to higher temperatures in a well-balanced manner.

The wiring patterns may be formed so as to extend to at least a near-center part of the mounting region of the integrated circuit element.

By thus having the wiring patterns of the electrodes for mounting purpose extend to a near-center part of the mounting region of the integrated circuit element, the wiring patterns may be efficiently heated by the heat release from the near-center part, and the heat from the heated wiring patterns may be transferred to the piezoelectric vibrator. As a result, the piezoelectric vibrator may be effectively heated to higher temperatures.

The integrated circuit element may include a temperature sensor, and the wiring patterns may be extending so as to overlap at least in part with a region of projection where the temperature sensor is projected in the mounting region of the integrated circuit element.

By thus forming the wiring patterns in a manner that they extend so as to overlap at least in part with the region of projection of the temperature sensor embedded in the integrated circuit element, heat from the temperature sensor-embedded part of the integrated circuit element may be effectively released toward the wiring patterns at least partly facing the temperature sensor-embedded part. As a result, the temperature of and around the temperature sensor may be decreased to lower degrees, and heat from the wiring patterns heated by the heat release from the temperature sensor-embedded part may be transferred to the piezoelectric vibrator and heat the piezoelectric vibrator to higher temperatures. This may rapidly dissipate possible temperature differences between the piezoelectric vibrator and the temperature sensor-embedded part, accelerating the arrival of thermal equilibrium.

The integrated circuit element may include an oscillator circuit and a temperature-compensated circuit.

Any temperature differences may be rapidly dissipated to achieve the state of thermal equilibrium between the piezoelectric vibrator and the integrated circuit element thus structured when this circuit element is driven and heated to higher temperatures. This may control possible frequency variations resulting from temperature differences between the temperature sensor and the piezoelectric vibrator, conducing to accurate temperature compensation.

In the piezoelectric vibration device, the integrated circuit element may have a rectangular shape in plan view, the plurality of mounting terminals may be formed at positions close to one of two pairs of opposing sides of the rectangular shape and arranged in two rows along the one of two pairs of opposing sides, and the wiring pattern may be formed so as to extend between the two rows along the one of two pairs of opposing sides in the mounting region of the integrated circuit element.

In the piezoelectric vibration device characterized in that the wiring pattern extends along a pair of opposing sides of the integrated circuit element rectangular in plan view between the two rows of mounting terminals formed at positions close to the pair of opposing sides. Thus, heat from the integrated circuit element driven and heated to higher temperatures may be efficiently released to the wiring patterns facing the integrated circuit element from an interval between the two rows of mounting terminals close to the outer circumference of the integrated circuit element, i.e., a center part of the integrated circuit element. Then, the integrated circuit element may be lowered in temperature. The heat of the wiring patterns heated by the heat release, on the other hand, may be transferred to the piezoelectric vibrator, and the piezoelectric vibrator may be rapidly heated to higher temperatures.

In the piezoelectric vibration device, an active surface of the integrated circuit element may be facing the plurality of electrodes for mounting purpose of the piezoelectric vibrator, and the plurality of mounting terminals of the integrated circuit element and the plurality of electrodes for mounting purpose of the piezoelectric vibrator may be electrically connected through a metallic material.

In the piezoelectric vibration device thus characterized, the piezoelectric vibrator and the active surface of the integrated circuit element are located in proximity. The heat of the piezoelectric vibrator, therefore, may be efficiently transferred to the integrated circuit element through the metallic material. This may allow the integrated circuit element to decrease in temperature and also allow the piezoelectric vibrator to increase in temperature, dissipating any temperature differences between the integrated circuit element and the piezoelectric vibrator.

An interval between the piezoelectric vibrator and the integrated circuit element may be filled with a sealing resin.

This may ensure an adequate mechanical strength between the integrated circuit element and the piezoelectric vibrator.

According to the another invention, at least one of the paired electrodes for mounting purpose that are electrically connected to the driving electrodes of the piezoelectric vibrating plate has a wiring pattern extending more inward in the mounting region of the integrated circuit element than the mounting terminals. This wiring pattern of the electrode for mounting purpose is, therefore, facing the integrated circuit element to be mounted. When the integrated circuit element is heated to higher temperatures under heat generated by the integrated circuit element driven to operate, the wiring pattern facing the integrated circuit element is heated by the heat released from the integrated circuit element.

This wiring pattern is electrically connected to the driving electrode of the piezoelectric vibrator. The heat from the heated wiring pattern is, therefore, transferred to the piezoelectric vibrator, by which the piezoelectric vibrator is heated. Then, the integrated circuit element at higher temperatures than the piezoelectric vibrator releases heat to the wiring pattern facing the integrated circuit element, dropping to lower temperatures. The piezoelectric vibrator, on the other hand, is subjected to the heat from the wiring pattern heated by the heat release from the integrated circuit element, increasing in temperature to higher degrees. This may control possible temperature differences between the piezoelectric vibrator and the integrated circuit element driven to operate, allowing the piezoelectric vibrator and the integrated circuit element to rapidly reach the state of thermal equilibrium.

The piezoelectric vibrator has a multilayered structure including three layers; the piezoelectric vibrating plate having main surfaces on which the driving electrodes are formed, and the first and second sealing members covering and sealing the main surfaces. The piezoelectric vibrator thus structured may be advantageously reduced in thickness (reduced in height) as compared with, for example, such a packaging structure that piezoelectric vibration pieces are housed in the housing space of a container and sealed with a lid member.

### REFERENCE SIGNS LIST

1 temperature-compensated piezoelectric oscillator
2 crystal vibrator
3 IC (integrated circuit element)
4 crystal vibrating plate
5 first sealing member
6 second sealing member
7 metal bump (metallic material)
8 underfill resin
31-36 first to sixth mounting terminals
301 temperature sensor
45, 46 first, second driving electrode
403, 404 first, second junction pattern for sealing purpose
51 first junction pattern for sealing purpose
501-506 first to sixth through electrodes
521-526 first to sixth electrodes for mounting purpose
531-536 first to sixth terminal junction
541-546 first to sixth electrode connector
561, 566 first, sixth wiring pattern
61 second junction pattern for sealing purpose
601-604 first to fourth through electrodes
631-634 first to fourth terminals for external connection
S mounting region

1. A piezoelectric vibration device, comprising:
a piezoelectric vibrator comprising a plurality of terminals for external connection and a plurality of electrodes for mounting purpose; and
an integrated circuit element including a plurality of mounting terminals connectable to the plurality of electrodes for mounting purpose, the integrated circuit element being mountable to the piezoelectric vibrator,
the piezoelectric vibrator comprising:
a piezoelectric vibrating plate including driving electrodes formed on main surfaces on both sides thereof;
a first sealing member allowed to cover and seal one of the main surfaces of the piezoelectric vibrating plate; and
a second sealing member allowed to cover and seal the other one of the main surfaces of the piezoelectric vibrating plate, wherein
the plurality of electrodes for mounting purpose are electrically connected to the driving electrodes formed on the main surfaces or to the plurality of terminals for external connection,
the plurality of mounting terminals in the integrated circuit element are formed at positions close to an outer circumference, and
at least one of the plurality of electrodes for mounting purpose electrically connected to the plurality of terminals for external connection has a wiring pattern extending more inward in a mounting region where the integrated circuit element is mounted than at least the plurality of mounting terminals.

2. The piezoelectric vibration device according to claim 1, wherein
the plurality of electrodes for mounting purpose and the wiring pattern are formed on an outer surface of the first sealing member,
the plurality of terminals for external connection are formed on an outer surface of the second sealing member, and
the piezoelectric vibrator comprises a plurality of through electrodes penetrating through the first sealing member, the piezoelectric vibrating plate and the second sealing member in a direction of thickness to provide electric connection between the plurality of electrodes for mounting purpose and the plurality of terminals for external connection.

3. The piezoelectric vibration device according to claim 1, wherein
the wiring pattern is extending inward in the mounting region of the integrated circuit element as far as at least a near-center part of the mounting region.

4. The piezoelectric vibration device according to claim 3, wherein
the wiring pattern is formed so as to electrically connect at least one of the plurality of electrodes for mounting purpose to the plurality of terminals for external connection.

5. The piezoelectric vibration device according to claim 3, wherein
the at least one of the plurality of electrodes for mounting purpose is electrically connected to one or more of the plurality of terminals for external connection electrically connected to an electronic component, which is a heat source, mounted to an external circuit board.

6. The piezoelectric vibration device according to claim 3, wherein
the integrated circuit element comprises a temperature sensor, and
the wiring pattern is extending so as to overlap at least in part with a region of projection where the temperature sensor is projected in the mounting region of the integrated circuit element.

7. The piezoelectric vibration device according to claim 3, wherein
the integrated circuit element has a rectangular shape in plan view,
the plurality of mounting terminals are formed at positions close to one of two pairs of opposing sides of the rectangular shape and arranged in two rows along the one of two pairs of opposing sides, and
the wiring pattern is formed so as to extend and traverse an interval between the two rows in the mounting region of the integrated circuit element.

8. The piezoelectric vibration device according to claim 7, wherein
the integrated circuit element is mounted on the piezoelectric vibrator in a manner that, of the plurality of electrodes for mounting purpose electrically connected to the driving electrodes formed on the main surfaces, a part of the plurality of electrodes for mounting purpose extending beyond the mounting region is located at a position close to the one of two pairs of opposing sides of the integrated circuit element.

9. The piezoelectric vibration device according to claim 3, wherein
an active surface of the integrated circuit element is facing the plurality of electrodes for mounting purpose of the piezoelectric vibrator, and
the plurality of mounting terminals of the integrated circuit element and the plurality of electrodes for mounting purpose of the piezoelectric vibrator are electrically connected through a metallic material.

10. The piezoelectric vibration device according to claim 3, wherein
an interval between the integrated circuit element and the piezoelectric vibrator is filled with a sealing resin.

11. The piezoelectric vibration device according to claim 2, wherein
the wiring pattern is extending inward in the mounting region of the integrated circuit element as far as at least a near-center part of the mounting region.
